(19) United States
(12) Patent Application Publication
(10) Pub. No.: US 2023/0359793 A1
(43) Pub. Date: Nov. 9, 2023

(54) MACHINE-LEARNING CALIBRATION FOR PETROLEUM SYSTEM MODELING

(71) Applicant: Schlumberger Technology Corporation, Sugar Land, TX (US)

(72) Inventors: Adrian KLEINE, Aachen (DE); Thomas HANTSCHEL, Aachen (DE)

(21) Appl. No.: 18/246,259

(22) PCT Filed: Sep. 23, 2021
(86) PCT No.: PCT/US2021/071560

§ 371 Date: Mar. 22, 2023

Related U.S. Application Data
(60) Provisional application No. 62/706,999, filed on Sep. 23, 2020.

(51) Int. Cl. G06F 30/28; G06N 5/022

(52) U.S. Cl. CPC G06F 30/28; G06N 5/022

(57) ABSTRACT

A method for simulating a subterranean volume includes receiving one or more input parameters and one or more simulation realizations representing the subterranean domain, modeling the one or more simulation realizations as a target function of the one or more input parameters, training a machine-learning model to predict values for the target function using the one or more input parameters and the one or more simulation realizations, predicting a value for the target function based on a first candidate simulation or a first candidate output parameter of a simulation, selecting the first candidate simulation, the first candidate output parameter, or both based on the predicted value of the target function, and simulating the subterranean volume using the first candidate output parameter, or both.

### CROSS-REFERENCE TO RELATED APPLICATIONS

This application claims priority to U.S. Provisional Patent Application having Ser. No. 62/706,999, which was filed on Sep. 23, 2020 and is incorporated herein by reference in its entirety.

### BACKGROUND

Basin and petroleum system modeling relates to simulating the geological evolution of sedimentary basin and its associated petroleum systems. Generally, a number of processes are considered, including pore pressure and compaction, rock stress and failure, temperature predictions as well as the geochemical processes inside organic rich source rocks and hydrocarbon migration and accumulation. One specific use case is pore pressure prediction on a basin scale, which can be used to assess drilling risks.

There generally exist uncertainties for various input parameters for this type of modeling. For example, in pore pressure prediction, input parameters that may include a degree of uncertainty may include rock permeabilities, compaction parameters, facies models, and paleo-erosion amounts. Data from existing wells can be used as validation points for petroleum system models and to control pressures and porosities at the well location.

Ensemble-based statistical approaches consider a number of different realizations of the input parameters, and thereby provide a mechanism to ensure that predicted pressures and porosities match the observed well parameter at the well location. Ensemble approaches may also enable predictions for pore pressure values into unknown areas, e.g., in areas in which a well may be planned to extend.

The number of realizations called for to accurately describe the uncertainty for the petroleum system model may be relatively high, often on the order of 100 to 10,000. As the costs associated with high-performance computing resources used to perform such simulations are also high, ensemble-based approaches may be economically impractical. Accordingly, basin and petroleum system modeling generally restricts the analysis to either the best case or a few selected manually created realizations, hence limiting the applicability of petroleum system modeling.

### SUMMARY

Embodiments of the disclosure include a method for simulating a subterranean volume that includes receiving one or more input parameters and one or more simulation realizations representing the subterranean volume, modeling the one or more simulation realizations as a target function of the one or more input parameters, training a machine-learning model to predict values for the target function using the one or more input parameters and the one or more simulation realizations, predicting a value for the target function based on a first candidate simulation or a first candidate output parameter of a simulation, selecting the first candidate simulation, the first candidate output parameter, or both based on the predicted value of the target function, and simulating the subterranean volume using the first candidate simulation, the first candidate output parameter, or both.

In an embodiment, the method includes predicting a second value for the target function based on at least one of a second candidate simulation or a second candidate output parameter, and determining not to simulate the subterranean volume using the second candidate simulation, the second candidate output parameter, or both based on the second value of the target function.

In an embodiment, selecting the first candidate simulation, the first candidate output parameter, or both is based on the first candidate simulation or the first candidate output parameter minimizing the first value of the target function.

In an embodiment, simulating the subterranean volume includes simulating the subterranean volume using an ensemble of different realizations including the selected first candidate simulation.

In an embodiment, the first candidate simulation, the first candidate output parameter, or both are selected for simulating prior to simulating the subterranean volume using the first candidate simulation, the first candidate output parameter, or both.

In an embodiment, predicting the first candidate output parameter includes determining one or more statistical characteristics for values of the first candidate output parameter.

In an embodiment, the method further includes generating a visualization of the subterranean volume based on simulating the subterranean volume using the first candidate simulation, the first candidate output parameter, or both.

In an embodiment, the method also includes adjusting a weight of a mud in a well based at least in part on the simulating, wherein the simulating is configured to predict a pore pressure, a fracture gradient, or both in a rock formation.

Embodiments of the disclosure also include a computing system including one or more processors, and a memory system including one or more non-transitory computer-readable media storing instructions that, when executed by the one or more processors, cause the computing system to perform operations. The operations include receiving one or more input parameters and one or more simulation realizations representing a subterranean volume, modeling the one or more simulation realizations as a target function of the one or more input parameters, training a machine-learning model to predict values for the target function using the one or more input parameters and the one or more simulation realizations, predicting a value for the target function based on a first candidate simulation or a first candidate output parameter of a simulation, selecting the first candidate simulation, the first candidate output parameter, or both based on the predicted value of the target function, and simulating the subterranean volume using the first candidate simulation, the first candidate output parameter, or both.

Embodiments of the disclosure also include a non-transitory computer-readable medium storing instructions that, when executed by one or more processors of a computing system, cause the computing system to perform operations. The operations include receiving one or more input parameters and one or more simulation realizations representing a subterranean volume, modeling the one or more simulation realizations as a target function of the one or more input parameters, training a machine-learning model to predict values for the target function using the one or more input parameters and the one or more simulation realizations, predicting a value for the target function based on a first candidate simulation or a first candidate output parameter of a simulation, selecting the first candidate simulation, the first candidate output parameter, or both based on the predicted value of the target function, and simulating the subterranean volume using the first candidate simulation, the first candidate output parameter, or both.

It will be appreciated that this summary is intended merely to introduce some aspects of the present methods, systems, and media, which are more fully described and/or claimed below. Accordingly, this summary is not intended to be limiting.

### BRIEF DESCRIPTION OF THE DRAWINGS

The accompanying drawings, which are incorporated in and constitute a part of this specification, illustrate embodiments of the present teachings and together with the description, serve to explain the principles of the present teachings. In the figures:

FIG. 1 illustrates an example of a system that includes various management components to manage various aspects of a geologic environment, according to an embodiment.

FIG. 2 illustrates a flowchart of a method for simulating a subterranean volume, according to an embodiment.

FIG. 3 illustrates a plot of modeled and simulated values for formation pressure and pore pressure along a depth of a well, the values for which may be predicted/modeled using an embodiment of the method of FIG. 2.

FIG. 4 illustrates an example of a geological evolution of a rock formation, which may be predicted/modeled using an embodiment of the method of FIG. 2.

FIG. 5 illustrates a schematic view of a computing system, according to an embodiment.

### DETAILED DESCRIPTION

Reference will now be made in detail to embodiments, examples of which are illustrated in the accompanying drawings and figures. In the following detailed description, numerous specific details are set forth in order to provide a thorough understanding of the invention. However, it will be apparent to one of ordinary skill in the art that the invention may be practiced without these specific details. In other instances, well-known methods, procedures, components, circuits, and networks have not been described in detail so as not to unnecessarily obscure aspects of the embodiments.

It will also be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

Attention is now directed to processing procedures, methods, techniques, and workflows that are in accordance with some embodiments. Some operations in the processing procedures, methods, techniques, and workflows disclosed herein may be combined and/or the order of some operations may be changed.

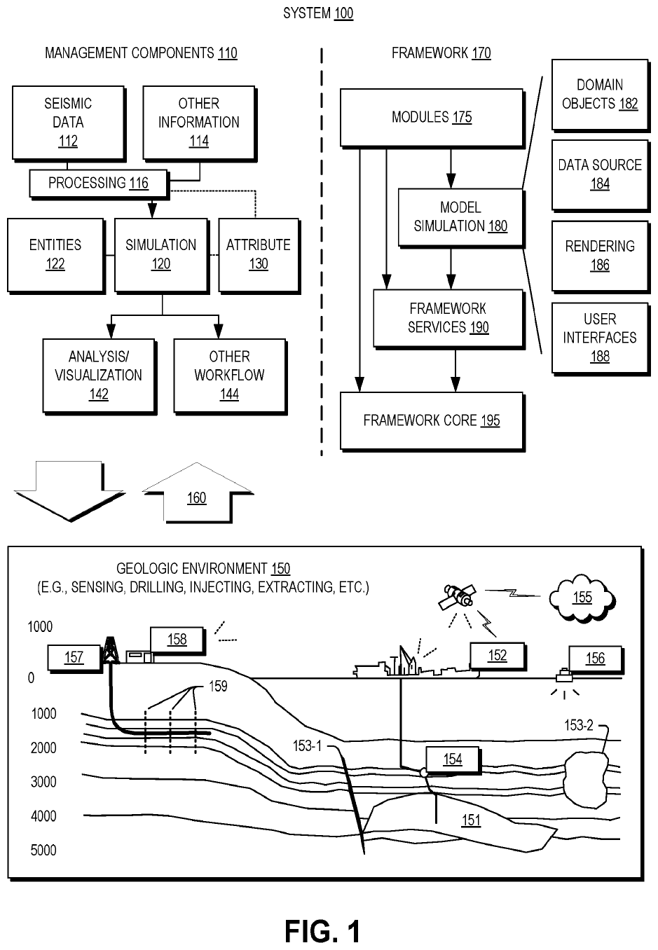

FIG. 1 illustrates an example of a system 100 that includes various management components 110 to manage various aspects of a geologic environment 150 (e.g., an environment that includes a sedimentary basin, a reservoir 151, one or more faults 153-1, one or more geobodies 153-2, etc.). For example, the management components 110 may allow for direct or indirect management of sensing, drilling, injecting, extracting, etc., with respect to the geologic environment 150. In turn, further information about the geologic environment 150 may become available as feedback 160 (e.g., optionally as input to one or more of the management components 110).

In the example of FIG. 1, the management components 110 include a seismic data component 112, an additional information component 114 (e.g., well/logging data), a processing component 116, a simulation component 120, an attribute component 130, an analysis/visualization component 142 and a workflow component 144. In operation, seismic data and other information provided per the components 112 and 114 may be input to the simulation component 120.

In an example embodiment, the simulation component 120 may rely on entities 122. Entities 122 may include earth entities or geological objects such as wells, surfaces, bodies, reservoirs, etc. In the system 100, the entities 122 can include virtual representations of actual physical entities that are reconstructed for purposes of simulation. The entities 122 may include entities based on data acquired via sensing, observation, etc. (e.g., the seismic data 112 and other information 114). An entity may be characterized by one or more properties (e.g., a geometrical pillar grid entity of an earth model may be characterized by a porosity property). Such properties may represent one or more measurements (e.g., acquired data), calculations, etc.

In an example embodiment, the simulation component 120 may operate in conjunction with a software framework such as an object-based framework. In such a framework, entities may include entities based on pre-defined classes to facilitate modeling and simulation. A commercially available example of an object-based framework is the MICROSOFT® .NET® framework (Redmond, Washington), which provides a set of extensible object classes. In the .NET® framework, an object class encapsulates a module of reusable code and associated data structures. Object classes can be used to instantiate object instances for use in by a program, script, etc. For example, borehole classes may define objects for representing boreholes based on well data.

In the example of FIG. 1, the simulation component 120 may process information to conform to one or more attributes specified by the attribute component 130, which may include a library of attributes. Such processing may occur prior to input to the simulation component 120 (e.g., consider the processing component 116). As an example, the simulation component 120 may perform operations on input information based on one or more attributes specified by the attribute component 130. In an example embodiment, the simulation component 120 may construct one or more models of the geologic environment 150, which may be relied on to simulate behavior of the geologic environment 150 (e.g., responsive to one or more acts, whether natural or artificial). In the example of FIG. 1, the analysis/visualization component 142 may allow for interaction with a model or model-based results (e.g., simulation results, etc.). As an example, output from the simulation component 120 may be input to one or more other workflows, as indicated by a workflow component 144.

As an example, the simulation component 120 may include one or more features of a simulator such as the ECLIPSE™ reservoir simulator (Schlumberger Limited, Houston Texas), the INTERSECT′ reservoir simulator (Schlumberger Limited, Houston Texas), etc. As an example, a simulation component, a simulator, etc. may include features to implement one or more meshless techniques (e.g., to solve one or more equations, etc.). As an example, a reservoir or reservoirs may be simulated with respect to one or more enhanced recovery techniques (e.g., consider a thermal process such as SAGD, etc.).

In an example embodiment, the management components 110 may include features of a commercially available framework such as the PETREL® seismic to simulation software framework (Schlumberger Limited, Houston, Texas). The PETREL® framework provides components that allow for optimization of exploration and development operations. The PETREL® framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of modeling, simulating, etc.).

In an example embodiment, various aspects of the management components 110 may include add-ons or plug-ins that operate according to specifications of a framework environment. For example, a commercially available framework environment marketed as the OCEAN® framework environment (Schlumberger Limited, Houston, Texas) allows for integration of add-ons (or plug-ins) into a PETREL® framework workflow. The OCEAN® framework environment leverages .NET® tools (Microsoft Corporation, Redmond, Washington) and offers stable, user-friendly interfaces for efficient development. In an example embodiment, various components may be implemented as add-ons (or plug-ins) that conform to and operate according to specifications of a framework environment (e.g., according to application programming interface (API) specifications, etc.).

FIG. 1 also shows an example of a framework 170 that includes a model simulation layer 180 along with a framework services layer 190, a framework core layer 195 and a modules layer 175. The framework 170 may include the commercially available OCEAN® framework where the model simulation layer 180 is the commercially available PETREL® model-centric software package that hosts OCEAN® framework applications. In an example embodiment, the PETREL® software may be considered a data-driven application. The PETREL® software can include a framework for model building and visualization.

As an example, a framework may include features for implementing one or more mesh generation techniques. For example, a framework may include an input component for receipt of information from interpretation of seismic data, one or more attributes based at least in part on seismic data, log data, image data, etc. Such a framework may include a mesh generation component that processes input information, optionally in conjunction with other information, to generate a mesh.

In the example of FIG. 1, the model simulation layer 180 may provide domain objects 182, act as a data source 184, provide for rendering 186 and provide for various user interfaces 188. Rendering 186 may provide a graphical environment in which applications can display their data while the user interfaces 188 may provide a common look and feel for application user interface components.

As an example, the domain objects 182 can include entity objects, property objects and optionally other objects. Entity objects may be used to geometrically represent wells, surfaces, bodies, reservoirs, etc., while property objects may be used to provide property values as well as data versions and display parameters. For example, an entity object may represent a well where a property object provides log information as well as version information and display information (e.g., to display the well as part of a model).

In the example of FIG. 1, data may be stored in one or more data sources (or data stores, generally physical data storage devices), which may be at the same or different physical sites and accessible via one or more networks. The model simulation layer 180 may be configured to model projects. As such, a particular project may be stored where stored project information may include inputs, models, results and cases. Thus, upon completion of a modeling session, a user may store a project. At a later time, the project can be accessed and restored using the model simulation layer 180, which can recreate instances of the relevant domain objects.

In the example of FIG. 1, the geologic environment 150 may include layers (e.g., stratification) that include a reservoir 151 and one or more other features such as the fault 153-1, the geobody 153-2, etc. As an example, the geologic environment 150 may be outfitted with any of a variety of sensors, detectors, actuators, etc. For example, equipment 152 may include communication circuitry to receive and to transmit information with respect to one or more networks 155. Such information may include information associated with downhole equipment 154, which may be equipment to acquire information, to assist with resource recovery, etc. Other equipment 156 may be located remote from a well site and include sensing, detecting, emitting or other circuitry. Such equipment may include storage and communication circuitry to store and to communicate data, instructions, etc. As an example, one or more satellites may be provided for purposes of communications, data acquisition, etc. For example, FIG. 1 shows a satellite in communication with the network 155 that may be configured for communications, noting that the satellite may additionally or instead include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. As an example, a well may be drilled for a reservoir that is laterally extensive. In such an example, lateral variations in properties, stresses, etc. may exist where an assessment of such variations may assist with planning, operations, etc. to develop a laterally extensive reservoir (e.g., via fracturing, injecting, extracting, etc.). As an example, the equipment 157 and/or 158 may include components, a system, systems, etc. for fracturing, seismic sensing, analysis of seismic data, assessment of one or more fractures, etc.

As mentioned, the system 100 may be used to perform one or more workflows. A workflow may be a process that includes a number of worksteps. A workstep may operate on data, for example, to create new data, to update existing data, etc. As an example, a may operate on one or more inputs and create one or more results, for example, based on one or more algorithms. As an example, a system may include a workflow editor for creation, editing, executing, etc. of a workflow. In such an example, the workflow editor may provide for selection of one or more pre-defined worksteps, one or more customized worksteps, etc. As an example, a workflow may be a workflow implementable in the PETREL® software, for example, that operates on seismic data, seismic attribute(s), etc. As an example, a workflow may be a process implementable in the OCEAN® framework. As an example, a workflow may include one or more worksteps that access a module such as a plug-in (e.g., external executable code, etc.).

In some embodiments of the present disclosure, an alternative to the computationally-intensive ensemble simulation technique is provided. In such embodiments, the outcome of a petroleum system model may be predicted by a machine-learning model instead of (or potentially in addition to in parallel with) a full simulation. This may reduce simulation costs, while improving the prediction quality of petroleum system modeling. As such, embodiments of the present disclosure may both improve efficiency and improve accuracy of the modeling process, which may in turn enhance exploration, drilling, production, and other oilfield activities.

In an embodiment, a simulation of a petroleum system model can be considered as an evaluation of a function ƒ. The input parameters of the function are given by the model input parameters considered to be uncertain: {x₁, x₂, . . . , x_{L}}=x, where L denotes the total number of input parameters and xᵢ the value of the i-th parameter (which could be e.g. a shift of a permeability of a specific lithology or a parameter used for compaction). Output parameters can be split into two different types: output where calibration data exists y₁, y₂, . . . , y_{M} and output for which a prediction should be performed: y_{M+1}, y_{M+2}, . . . , y_{M+N}. A simulation of a specific realization can now be considered as an evaluation of a function:

ƒ(x)=y={y₁, . . . ,y_{M},y_{M+1}, . . . ,y_{M+N}}

One approach to model an ensemble of realizations is to define a target function:

$${χ}^{2} ( \underline{x} ) = {\sum }_{i = 1}^{M} \frac{{[ {f}_{i} ( \underline{x} ) - \overline{{y}_{i}} ]}^{2}}{{σ}_{i}^{2}} ,$$

where y̅ᵢ̅ denotes the measured value of the i-th validation parameter, and σᵢ the uncertainty of this validation parameter (e.g., introduced by measurement uncertainties but it also reflects model uncertainties). Realizations that are able to reproduce the validation parameter may be considered to minimize the target function. Using various methods, a set of realizations can be selected that minimize or otherwise generate low values for the target function (defined by certain rules). The values of the simulated output parameters y_{M+1}, y_{M+2}, . . . , y_{M+N} can now be used calculate expectation values and distributions of unknown parameters (for instance, pore pressures at a to-be-drilled well trajectory).

Machine learning may be considered to model generic functions. A machine-learning model is trained with a set of known data points {x^{(k)}, y^{(k)}} to obtain a function ƒ_{ML} as an approximation, e.g.: ƒ_{ML}(x^{(k)})≈y^{(k)}. Note that it is possible to either build a model with only a single target quantity, e.g. which reproduces yᵢ for a single i, or to build models with multiple target quantities. A number of different machine-learning algorithms exists, e.g. Random forests or gradient boosting trees.

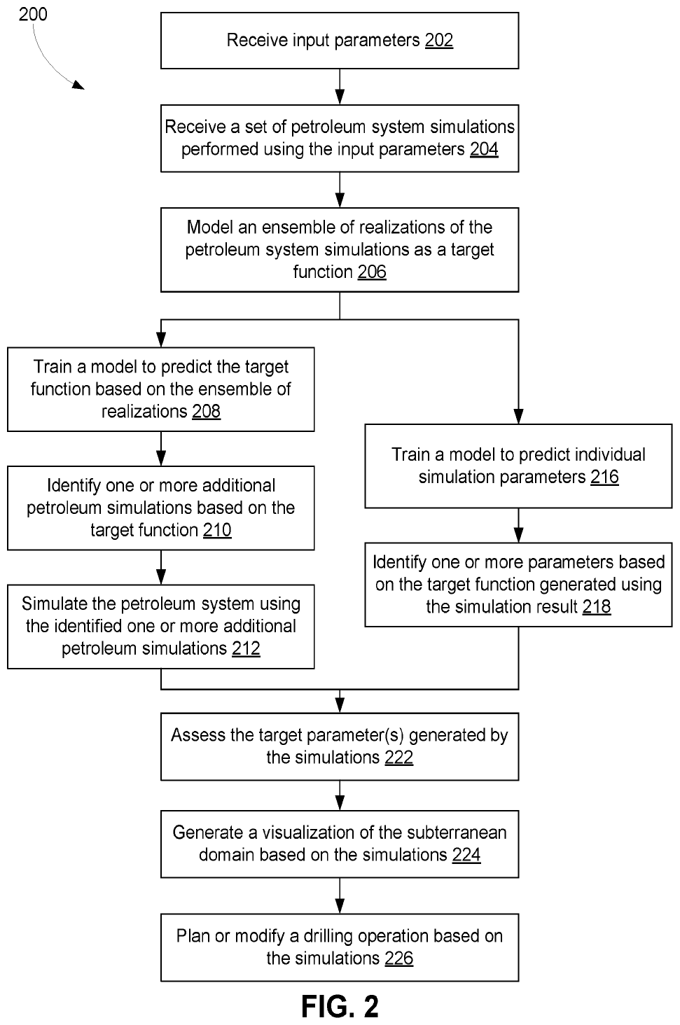

FIG. 2 illustrates a flowchart of a method 200 that may be used to model a subterranean domain, e.g., using the ensemble model and machine-learning model discussed above, according to an embodiment. The method 200 may include receiving input parameters, as at 202, and receiving a set of petroleum system simulations performed using the input parameters, as at 204. More specifically, the method 200 may start with a set of realizations (input parameters, x) for which a full petroleum system simulation has been performed (yielding y). The set of realization may cover the full parameter space, for example with Latin Hyper Cube sampling.

The method 200 may then include modeling an ensemble of realizations of the petroleum system simulations as a target function χ²(x), as at 206, as described above.

The method 200 may then select one of two paths or may conduct these two paths in parallel or in series and combine the results thereof. The first path begins at 208, where a machine-learning model is trained to predict the target function based on the set of ensemble realizations, as at 208. In other words, the ensemble is used to train a machine-learning model to predict χ² (x), without having to compute the entire simulation. The machine learning model may then be implemented to predict the target function.

The prediction is used to identify/select one or more new realizations, based on the value of the target function associated with the realizations, as at 210. For example, lower values for the target function may represent suitable candidates for new realizations to be added to the ensemble. These identified simulations may then be run (computed) and added to the ensemble, as at 212. As such, the impact and/or accuracy of the new simulations is first predicted prior to expending the resources to conduct the simulation. Accordingly, at least some candidate simulations may be included based on resulting in low values for the target function (e.g., minimizing the target function), while others may be disregarded without simulation, based on a prediction that they do not result in a low target function value.

In the other path, one or more machine-learning models may be trained to predict individual simulation output parameters, as at 216. These predictions may be employed to identify specific (output) parameters for inclusion in the ensemble simulations, as at 218. In other words, the ensemble may be used to train machine-learning models to predict ƒ(x) (targeting either one parameter per machine-learning model or a multiple parameter per machine-learning model). These predictions can then be used to reduce (e.g., minimize) χ²(x).

In this aspect of the method 200, the selection which “candidate” (one or a subset of possible choices) output parameter y may be included may be made prior to the simulations being performed. For example, a value of the pore pressure at 1000 m depth for a set of input parameters may be predicted. This may provide insight into statistical characteristics (e.g., distributions) of the output parameter (including quantities such as average, variance, P10/P50/P90, etc.). As such, additional simulations may not be called for.

The machine-learning model's prediction and/or the simulated output values may be used to assess the target parameter y_{M+1}, y_{M+2}, . . . , y_{M+N} considering both expectation values as well as variances (other statistical quantities might also be considered), as at 222. Depending on this, the method 200 may be iteratively repeated or considered as completed.

As a result of the ensemble simulations, a visualization of the subterranean domain including, for example, simulated pore pressure, fluid flow regimes, geology, lithology, facies models, basin models, etc. may be produced, as at 224. Such visualization may be a digital model that is displayed on a computer display. Further, based on the simulation and/or the visualization, a drilling operation may be planned or modified, as at 226. For example, drilling parameters, trajectory, geometry, etc., may be modified based on pore pressure, e.g., as predicted using the method 200.

A variety of practical use-cases are contemplated, and others may be developed based on the present disclosure. For example, pre-pressure and rock stress predictions may be made, which may facilitate the drilling process. More particularly, an area may include a number of wells, each with measured pressure data generated based on mud weights, drill stem tests, leak-off tests, etc. A geological model may also be constructed to represent the area. The pressure and rock stress distribution for a to-be-drilled well may thus be predicted. Such prediction may proceed by using a basin model to predict pressures. The predictions may be validated/calibrated against existing pressure data (e.g., from existing wells). An embodiment of the present method may then be employed to predict pressure and rock stress for the target well, e.g., without running at least some of the model realizations (or using a subset of the parameters) that might otherwise be used with a full model simulation of an ensemble of realizations.

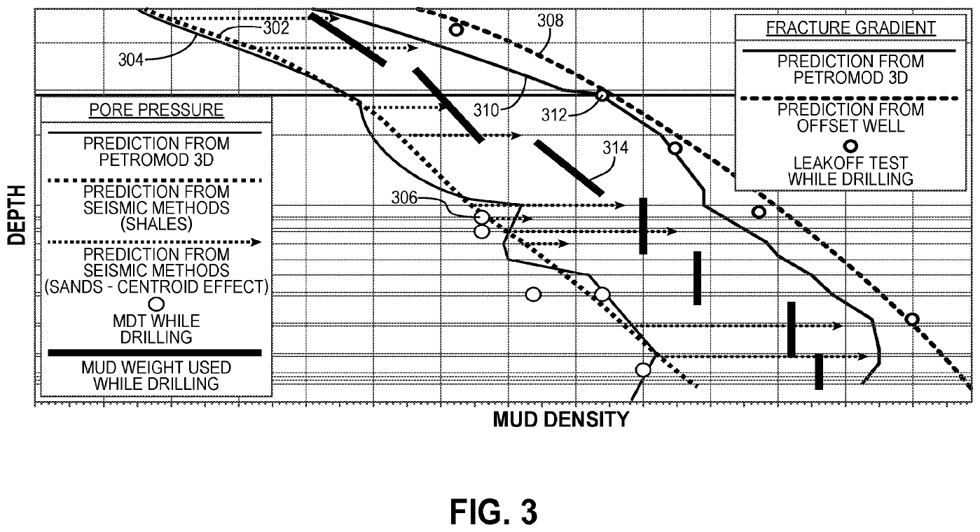

FIG. 3 illustrates one particular example of a visualization of the output of the method 200. As shown, the pre pressure and fracture gradient are plotted, with depth on the vertical axis and mud density on the horizontal. Specifically, the plot illustrates two different predictions for pore pressure 302, 304, where the prediction 302 is based on seismic methods and the prediction 304 is based on a modeling engine (e.g., PetroMod). Mud density measurements 306 are taken intermittently along the depth. Similarly, fracture gradient is predicted along line 310 from a modeling engine and predicted along line 308 based on an offset well. Leakoff testing is conducted at several points 312 along the depth of the well. Mud weights 314 are selected so as to remain between the predicted pore pressures and formation gradient, and thereby avoid damaging the well. The models may be calibrated using the measured pressure/gradient.

As can be seen in FIG. 3, however, measurements of these values may not be available as a drill bit is advancing into the earth, and thus may be modeled. More accurate predictions of the pore pressure and fracture gradients may permit fewer stops of the drill bit to permit measurements to be taken.

Another use case may be hydrocarbon quality (e.g., composition) prediction in a reservoir. In this case, petroleum systems models (e.g., models of basin temperatures, pressures, geochemical processes such as hydrocarbon generation, migration, accumulation over geological times) may be used to predict hydrocarbon quality (e.g., compositions, densities (API gravity), gas-oil-ratio). Embodiments of the present disclosure may be used to calibrate against existing values of known/existing neighboring oil fields and/or to analyze the impact of uncertainties (e.g., thermal evolution of the basin, geochemical properties, etc.).

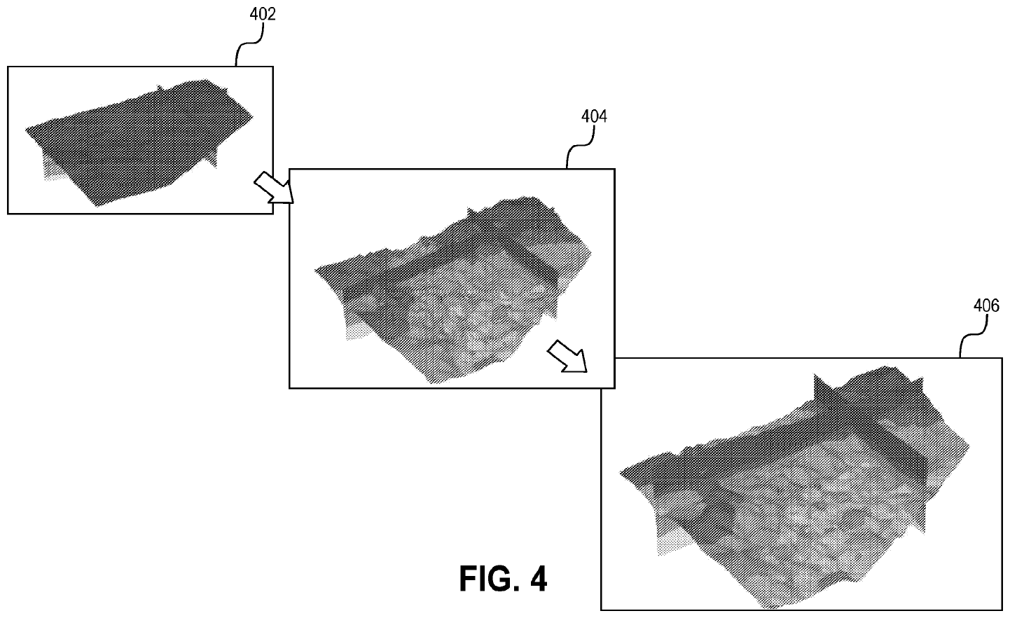

For example, FIG. 4 illustrates an evolution of a source rock over a geological time, as represented by a digital model that may be constructed as a visualization of the output that may be used by an engineer to plan and/or drill a well. As shown, the rock may begin, e.g., 100 or more million years ago as immature rock at 402. At an intermediate stage, e.g., 50 million years ago, salt windows open, which may result in peak oil generation. Stage 404 may represent present day. As will be appreciated, a large number of factors may account for the evolution of the rock, which may be modeled so as to accurately represent the rock at present day and predict the location of oil reservoirs, behavior of the rock, etc. Thus, embodiments of the present disclosure may permit more efficient generation of more accurate basin/rock models. Further, the output of the use cases presented herein may, in turn, be employed to adjust physical parameters of drilling equipment, mud weight parameters, etc.

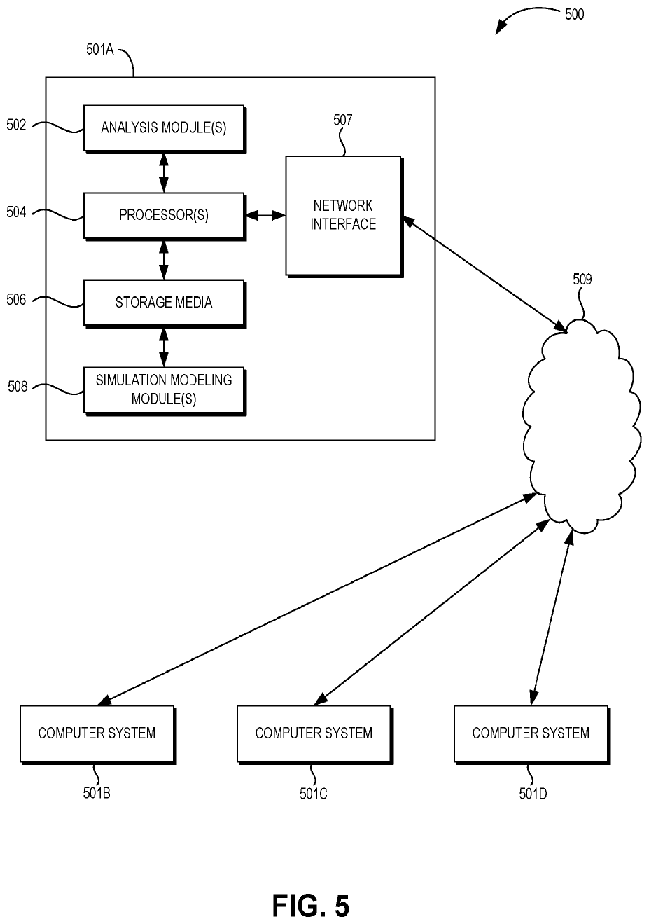

In some embodiments, the methods of the present disclosure may be executed by a computing system. FIG. 5 illustrates an example of such a computing system 500, in accordance with some embodiments. The computing system 500 may include a computer or computer system 501A, which may be an individual computer system 501A or an arrangement of distributed computer systems. The computer system 501A includes one or more analysis modules 502 that are configured to perform various tasks according to some embodiments, such as one or more methods disclosed herein. To perform these various tasks, the analysis module 602 executes independently, or in coordination with, one or more processors 504, which is (or are) connected to one or more storage media 506. The processor(s) 504 is (or are) also connected to a network interface 507 to allow the computer system 501A to communicate over a data network 509 with one or more additional computer systems and/or computing systems, such as 501B, 501C, and/or 501D (note that computer systems 501B, 501C and/or 501D may or may not share the same architecture as computer system 501A, and may be located in different physical locations, e.g., computer systems 501A and 501B may be located in a processing facility, while in communication with one or more computer systems such as 501C and/or 501D that are located in one or more data centers, and/or located in varying countries on different continents).

A processor may include a microprocessor, microcontroller, processor module or subsystem, programmable integrated circuit, programmable gate array, or another control or computing device.

The storage media 506 may be implemented as one or more computer-readable or machine-readable storage media. Note that while in the example embodiment of FIG. 5 storage media 506 is depicted as within computer system 501A, in some embodiments, storage media 506 may be distributed within and/or across multiple internal and/or external enclosures of computing system 501A and/or additional computing systems. Storage media 506 may include one or more different forms of memory including semiconductor memory devices such as dynamic or static random access memories (DRAMs or SRAMs), erasable and programmable read-only memories (EPROMs), electrically erasable and programmable read-only memories (EEPROMs) and flash memories, magnetic disks such as fixed, floppy and removable disks, other magnetic media including tape, optical media such as compact disks (CDs) or digital video disks (DVDs), BLURAY® disks, or other types of optical storage, or other types of storage devices. Note that the instructions discussed above may be provided on one computer-readable or machine-readable storage medium, or may be provided on multiple computer-readable or machine-readable storage media distributed in a large system having possibly plural nodes. Such computer-readable or machine-readable storage medium or media is (are) considered to be part of an article (or article of manufacture). An article or article of manufacture may refer to any manufactured single component or multiple components. The storage medium or media may be located either in the machine running the machine-readable instructions, or located at a remote site from which machine-readable instructions may be downloaded over a network for execution.

In some embodiments, computing system 500 contains one or more simulation modeling module(s) 508. In the example of computing system 500, computer system 501A includes the simulation modeling module 508. In some embodiments, a single simulation modeling module may be used to perform some aspects of one or more embodiments of the methods disclosed herein. In other embodiments, a plurality of simulation modeling modules may be used to perform some aspects of methods herein.

It should be appreciated that computing system 500 is merely one example of a computing system, and that computing system 500 may have more or fewer components than shown, may combine additional components not depicted in the example embodiment of FIG. 5, and/or computing system 500 may have a different configuration or arrangement of the components depicted in FIG. 5. The various components shown in FIG. 5 may be implemented in hardware, software, or a combination of both hardware and software, including one or more signal processing and/or application specific integrated circuits.

Further, the steps in the processing methods described herein may be implemented by running one or more functional modules in information processing apparatus such as general purpose processors or application specific chips, such as ASICs, FPGAs, PLDs, or other appropriate devices. These modules, combinations of these modules, and/or their combination with general hardware are included within the scope of the present disclosure.

Computational interpretations, models, and/or other interpretation aids may be refined in an iterative fashion; this concept is applicable to the methods discussed herein. This may include use of feedback loops executed on an algorithmic basis, such as at a computing device (e.g., computing system 500, FIG. 5), and/or through manual control by a user who may make determinations regarding whether a given step, action, template, model, or set of curves has become sufficiently accurate for the evaluation of the subsurface three-dimensional geologic formation under consideration.

The foregoing description, for purpose of explanation, has been described with reference to specific embodiments. However, the illustrative discussions above are not intended to be exhaustive or limiting to the precise forms disclosed. Many modifications and variations are possible in view of the above teachings. Moreover, the order in which the elements of the methods described herein are illustrate and described may be re-arranged, and/or two or more elements may occur simultaneously. The embodiments were chosen and described in order to best explain the principals of the disclosure and its practical applications, to thereby enable others skilled in the art to best utilize the disclosed embodiments and various embodiments with various modifications as are suited to the particular use contemplated.

What is claimed is:

1. A method for simulating a subterranean volume, comprising:
receiving one or more input parameters and one or more simulation realizations representing the subterranean volume;
modeling the one or more simulation realizations as a target function of the one or more input parameters;
training a machine-learning model to predict values for the target function using the one or more input parameters and the one or more simulation realizations;
predicting a value for the target function based on a first candidate simulation or a first candidate output parameter of a simulation;
selecting the first candidate simulation, the first candidate output parameter, or both based on the predicted value of the target function; and
simulating the subterranean volume using the first candidate simulation, the first candidate output parameter, or both.

2. The method of claim 1, further comprising:
predicting a second value for the target function based on at least one of a second candidate simulation or a second candidate output parameter; and
determining not to simulate the subterranean volume using the second candidate simulation, the second candidate output parameter, or both based on the second value of the target function.

3. The method of claim 1, wherein selecting the first candidate simulation, the first candidate output parameter, or both is based on the first candidate simulation or the first candidate output parameter minimizing the first value of the target function.

4. The method of claim 1, wherein simulating the subterranean volume comprises simulating the subterranean volume using an ensemble of different realizations including the selected first candidate simulation.

5. The method of claim 1, wherein the first candidate simulation, the first candidate output parameter, or both are selected for simulating prior to simulating the subterranean volume using the first candidate simulation, the first candidate output parameter, or both.

6. The method of claim 1, wherein predicting the first candidate output parameter comprises determining one or more statistical characteristics for values of the first candidate output parameter.

7. The method of claim 1, further comprising generating a visualization of the subterranean volume based on simulating the subterranean volume using the first candidate simulation, the first candidate output parameter, or both.

8. The method of claim 1, further comprising adjusting a weight of a mud in a well based at least in part on the simulating, wherein the simulating is configured to predict a pore pressure, a fracture gradient, or both in a rock formation.

9. A computing system, comprising:
one or more processors; and
a memory system comprising one or more non-transitory computer-readable media storing instructions that, when executed by the one or more processors, cause the computing system to perform operations, the operations comprising:
receiving one or more input parameters and one or more simulation realizations representing a subterranean volume;
modeling the one or more simulation realizations as a target function of the one or more input parameters;
training a machine-learning model to predict values for the target function using the one or more input parameters and the one or more simulation realizations;
predicting a value for the target function based on a first candidate simulation or a first candidate output parameter of a simulation;
selecting the first candidate simulation, the first candidate output parameter, or both based on the predicted value of the target function; and
simulating the subterranean volume using the first candidate simulation, the first candidate output parameter, or both.

10. The computing system of claim 9, wherein the operations further comprise:
predicting a second value for the target function based on at least one of a second candidate simulation or a second candidate output parameter; and
determining not to simulate the subterranean volume using the second candidate simulation, the second candidate output parameter, or both based on the second value of the target function.

11. The computing system of claim 9, wherein selecting the first candidate simulation, the first candidate output parameter, or both is based on the first candidate simulation or the first candidate output parameter minimizing the first value of the target function.

12. The computing system of claim 9, wherein simulating the subterranean volume comprises simulating the subterranean volume using an ensemble of different realizations including the selected first candidate simulation.

13. The computing system of claim 9, wherein the first candidate simulation, the first candidate output parameter, or both are selected for simulating prior to simulating the subterranean volume using the first candidate simulation, the first candidate output parameter, or both.

14. The computing system of claim 9, wherein predicting the first candidate output parameter comprises determining one or more statistical characteristics for values of the first candidate output parameter.

15. The computing system of claim 9, wherein the operations further comprise generating a visualization of the subterranean volume based on simulating the subterranean volume using the first candidate simulation, the first candidate output parameter, or both.

16. The computing system of claim 9, wherein the operations further comprise adjusting a weight of a mud in a well based at least in part on the simulating, wherein the simulating is configured to predict a pore pressure, a fracture gradient, or both in a rock formation.

17. A non-transitory computer-readable medium storing instructions that, when executed by one or more processors of a computing system, cause the computing system to perform operations, the operations comprising:
receiving one or more input parameters and one or more simulation realizations representing a subterranean volume;
modeling the one or more simulation realizations as a target function of the one or more input parameters;
training a machine-learning model to predict values for the target function using the one or more input parameters and the one or more simulation realizations;
predicting a value for the target function based on a first candidate simulation or a first candidate output parameter of a simulation;
selecting the first candidate simulation, the first candidate output parameter, or both based on the predicted value of the target function; and
simulating the subterranean volume using the first candidate simulation, the first candidate output parameter, or both.

18. The medium of claim 17, wherein the operations further comprise:
predicting a second value for the target function based on at least one of a second candidate simulation or a second candidate output parameter; and
determining not to simulate the subterranean volume using the second candidate simulation, the second candidate output parameter, or both based on the second value of the target function.

19. The medium of claim 17, wherein selecting the first candidate simulation, the first candidate output parameter, or both is based on the first candidate simulation or the first candidate output parameter minimizing the first value of the target function.

20. The medium of claim 17, wherein simulation the subterranean volume comprises simulating the subterranean volume using an ensemble of different realizations including the selected first candidate simulation.
